(19) United States
(12) Patent Application Publication
(10) Pub. No.: US 2026/0101749 A1
(43) Pub. Date: Apr. 9, 2026

(54) SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Ming-Tsu Chung, Hsinchu City (TW); Yung-Chi Lin, New Taipei City (TW)

(73) Assignee: Taiwan Semiconductor Manufacturing Company, Ltd., Hsinchu (TW)

(21) Appl. No.: 18/817,210

(22) Filed: Aug. 27, 2024

(51) Int. Cl. H01L 23/00; H01L 21/56; H01L 23/18; H01L 23/31; H01L 23/373; H01L 25/065

(52) U.S. Cl. CPC H10W 40/259; H10W 74/016; H10W 74/121; H10W 76/42; H10W 90/00; H10W 72/01331; H10W 72/01338; H10W 72/01359; H10W 72/322; H10W 72/353; H10W 74/00; H10W 80/312; H10W 90/734; H10W 90/794

(57) ABSTRACT

A semiconductor package includes a substrate, a device die, an encapsulating material, a thermal conductive layer, a filling material, and a carrier. The device die is disposed over the substrate. The encapsulating material is disposed over the substrate and laterally encapsulates the device die. The thermal conductive layer conformally covers the device die and the encapsulating material, wherein a profile of the thermal conductive layer comprises a valley portion. The filling material is disposed over the thermal conductive layer and fills the valley portion, wherein a thermal conductivity of the thermal conductive layer is higher than a thermal conductivity of the filling material. The carrier is bonded to the thermal conductive layer and the filling material.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 illustrates a cross sectional views of intermediate stages in the manufacturing of a semiconductor package according to some embodiments of the present disclosure.

FIG. 10A illustrates a partial cross sectional view of the semiconductor package according to some embodiments of the present disclosure.

FIG. 10B illustrates a partial cross sectional view of the semiconductor package according to some embodiments of the present disclosure.

FIG. 10C illustrates a partial cross sectional view of the semiconductor package according to some embodiments of the present disclosure.

FIG. 11 to FIG. 15 illustrates a cross sectional views of intermediate stages in the manufacturing of a semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided in accordance with various embodiments. The intermediate stages of forming the package are illustrated in accordance with some embodiments. Some variations of some embodiments are discussed. Throughout the various views and illustrative embodiments, like reference numbers are used to designate like elements. It is appreciated that although the formation of System-on-Integrated-Chips (SoIC) packages is used as examples to explain the concept of the embodiments of the present disclosure, the embodiments of the present disclosure are readily applicable to other packages.

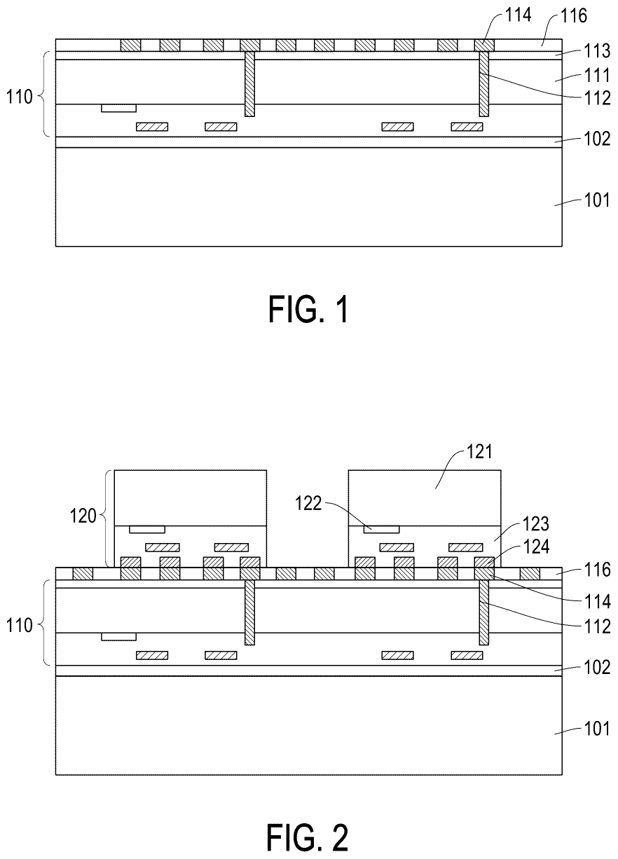

FIG. 1 to FIG. 9 illustrates a cross sectional views of intermediate stages in the manufacturing of a semiconductor package according to some embodiments of the present disclosure. Referring to FIG. 1, in some embodiments, a wafer (or a substrate) 110 is provided over a carrier 101. In some embodiments, the wafer 110 may include a plurality of dies 110, with some details of one of dies 110 illustrated. In one embodiment, each of the dies 110 may be a system on chip (SOC), or the like. In other embodiment, the wafer 110 may be an interposer wafer, which is free from active devices such as transistors and/or diodes. The interposer wafer may be free from passive devices such as capacitors, inductors, resistors, or the like, or may include passive devices. In some embodiments, the carrier 101 may be a glass carrier. In some embodiments, a de-bonding layer 102 may be provided over the carrier 101 for bonding the carrier 101 and the wafer 110. In one embodiment, the de-bonding layer 102 is a light-to heat-conversion (LTHC) release layer, for example. The materials of the carrier 101 and the de-bonding layer 102 are not limited in this disclosure.

In accordance with some embodiments of the present disclosure, the wafer 110 includes semiconductor substrate 111 and the features formed over semiconductor substrate 111. The semiconductor substrate 111 may be formed of crystalline silicon, crystalline germanium, crystalline silicon germanium, and/or a III-V compound semiconductor such as GaAsP, AlInAs, AlGaAs, GaInAs, GaInP, GaInAsP, and the like. The semiconductor substrate 111 may also be formed of other rigid materials such as glass, silicon oxide, silicon carbide, or the like. In some embodiments, the semiconductor substrate 111 may also be a bulk silicon substrate.

In one embodiments, at least one dielectric layer 113 is formed over the semiconductor substrate 111. In accordance with some embodiments of the present disclosure, the dielectric layer 113 is formed of silicon oxide, silicon nitride, silicon carbide, silicon oxynitride, silicon oxy-carbide, or the like. In accordance with some embodiments, the dielectric layer 113 is formed of silicon oxide, a thermal oxidation may be performed on semiconductor substrate 111 to form oxide layer.

In some embodiments, over the semiconductor substrate 111 (and the dielectric layer 113) resides interconnect structure 115. It is noted that FIG. 1 illustrates the interconnect structure 115 schematically, and the disclosure is not limited thereto. In some embodiments, the interconnect structure 115 includes metal lines/contacts, which are formed in dielectric layers. The dielectric layers are alternatively referred to as Inter-Metal Dielectric (IMD) layers hereinafter. In accordance with some embodiments of the present disclosure, at least the lower layers of dielectric layers are formed of low-k dielectric materials, which may have dielectric constants (k-value) lower than about 3.0. The dielectric layers may be formed of Black Diamond (a registered trademark of Applied Materials), a carbon-containing low-k dielectric material, Hydrogen SilsesQuioxane (HSQ), MethylSilsesQuioxane (MSQ), or the like. In accordance with alternative embodiments of the present disclosure, some or all of dielectric layers are formed of non-low-k dielectric materials such as silicon oxide, silicon carbide (SiC), silicon carbo-nitride (SiCN), silicon oxy-carbo-nitride (SiOCN), or the like. In accordance with some embodiments of the present disclosure, the formation of dielectric layers 32 includes depositing a porogen-containing dielectric material, and then performing a curing process to drive out the porogen, and hence the remaining dielectric layers are porous. Etch stop layers (not shown), which may be formed of silicon carbide, silicon nitride, or the like, are formed between IMD layers, and are not shown for simplicity.

In accordance with some embodiments of the present disclosure, the interconnect structure 115 includes a plurality of metal layers that are interconnected through vias. The metal layers may be formed of copper or copper alloys, and they can also be formed of other metals. The formation process may include single damascene process and dual damascene process. In an example of the single damascene process, a trench is first formed in one of dielectric layers, followed by filling the trench with a conductive material. A planarization process such as a Chemical Mechanical Polish (CMP) process is then performed to remove the excess portions of the conductive material higher than the top surface of the IMD layer, leaving a metal line in the trench. In a dual damascene process, both a trench and a via opening are formed in an IMD layer, with the via opening underlying and connected to the trench. The conductive material is then filled into the trench and the via opening to form a metal line and a via, respectively.

In some embodiments, a plurality of through vias (or through substrate vias (TSVs)) 112 are formed to extend through the semiconductor substrate 111. The TSVs 112 are electrically connected to the interconnect structure 115. The TSVs 112 may be formed by forming openings in the semiconductor substrate 111 and filling the openings with electrically conductive material(s). In one embodiment, the openings may extend into the semiconductor substrate 111 without extending through the substrate 111. In some embodiments, the conductive material filled the TSVs 112 may include copper, although other suitable materials such as aluminum, tungsten, alloys, doped polysilicon, combinations thereof, and the like, may alternatively be utilized. The conductive material may be formed by depositing a seed layer and then electroplating copper onto the seed layer, filling and overfilling the openings for the TSV 112. A planarization process, such as CMP, may be performed next to remove excess portions of the conductive material disposed outside the openings for the TSV 112.

In some embodiments, the wafer 110 further includes surface dielectric layer 116 formed at its top surface. The surface dielectric layer 116 is formed of a non-low-k dielectric material such as silicon oxide. The surface dielectric layer 116 is alternatively referred to as a passivation layer since it has the function of isolating the underlying low-k dielectric layers (if any) from the adverse effect of moisture and detrimental chemicals. The surface dielectric layer 116 may also have a composite structure including more than one layer, which may be formed of silicon oxide, silicon nitride, Undoped Silicate Glass (USG), or the like.

In some embodiments, a plurality of bond pads 114 are formed in surface dielectric layer 1168 and are electrically connected to the TSVs 112. In accordance with some embodiments of the present disclosure, the bond pads 114 are formed through a single damascene process, and may also include barrier layers and a copper-containing material formed over the respective barrier layers. In accordance with alternative embodiments of the present disclosure, the bond pads 114 are formed through a dual damascene process. The top surface dielectric layer 116 and the bond pads 114 are planarized so that their top surfaces are coplanar, which may be resulted due to the CMP in the formation of the bond pads 114.

Next, a plurality of device dies 120 are bonded over the wafer 110, as shown in FIG. 2. In accordance with some embodiments of the present disclosure, each of device dies 120 may also include memory dies. In some embodiments, each of device dies 120 may be a Central Processing Unit (CPU) die, a Micro Control Unit (MCU) die, an input-output (IO) die, a BaseBand (BB) die, an Application processor (AP) die, or the like. In addition, the device dies 120 may be different types of dies selected from the above-listed types. Also, one of device dies 120 may be a digital circuit die, while the other may be an analog circuit die. The device dies 120 in combination function as a system. Splitting the functions and circuits of a system into different dies may optimize the formation of these dies, and may achieve the reduction of manufacturing cost.

The device dies 120 may include semiconductor substrates 121, respectively, which may be silicon substrates. In some embodiments, integrated circuit devices 122, which may include active devices such as transistors and/or diodes, and passive devices such as capacitors, resistors, or the like are formed in the device dies 120. Also, the device dies 120 include interconnect structures 123, respectively, for connecting to the active devices and passive devices in the device dies 120. The interconnect structures 123 include metal lines and vias.

In some embodiments, each of the device dies 120 includes a plurality of bond pads 124. In one embodiment, the bonding may be achieved through hybrid bonding. For example, the bond pads 114 of the wafer 110 are bonded to the bond pads 124 of the device dies 120 through metal-to-metal direct bonding. In accordance with some embodiments of the present disclosure, the metal-to-metal direct bonding includes a copper-to-copper direct bonding. Furthermore, the dielectric layers 116 of the wafer 110 are bonded to the dielectric layers of the device dies 120 through fusion bonding.

To achieve the hybrid bonding, the device dies 120 are first pre-bonded to the dielectric layer 116 and bond pads 114 by lightly pressing the device dies 120 against the wafer 110. Although two device dies 120 are illustrated, the hybrid bonding may be performed at wafer level, and a plurality of device die groups identical to the illustrated die group (which include device dies 120) are pre-bonded, and arranged as rows and columns.

After all the device dies 120 are pre-bonded, an anneal is performed to cause the inter-diffusion of the metals in the bond pads 114 and the corresponding overlying bond pads 124. The annealing temperature may be in the range between about 200° and about 400° C., and may be in the range between about 300° and about 400° C. in accordance with some embodiments. The annealing time may be in the range between about 1.5 hours and about 3.0 hours, and may be in the range between about 1.5 hours and about 2.5 hours in accordance with some embodiments. The bond pads 124 are bonded to the corresponding bond pads 114 through direct metal bonding caused by metal inter-diffusion.

The dielectric layer 116 is also bonded to the dielectric layers of the device dies 120, with bonds formed therebetween. For example, the atoms (such as oxygen atoms) in one of the dielectric layers form chemical or covalence bonds with the atoms (such as silicon atoms) in the other one of dielectric layers. The resulting bonds between the dielectric layers 116 of the wafer 110 and the dielectric layers of the device dies 120 are dielectric-to-dielectric bonds.

In an alternative embodiment, the device dies 120 may be bonded to the wafer 110 through a plurality of external connectors disposed between the bond pads 114 and the bond pads 124. In such embodiments, an underfill material may be formed between the device dies 120 and the wafer 110 to at least encapsulate the external connectors after the device dies 120 are attached to the wafer 110.

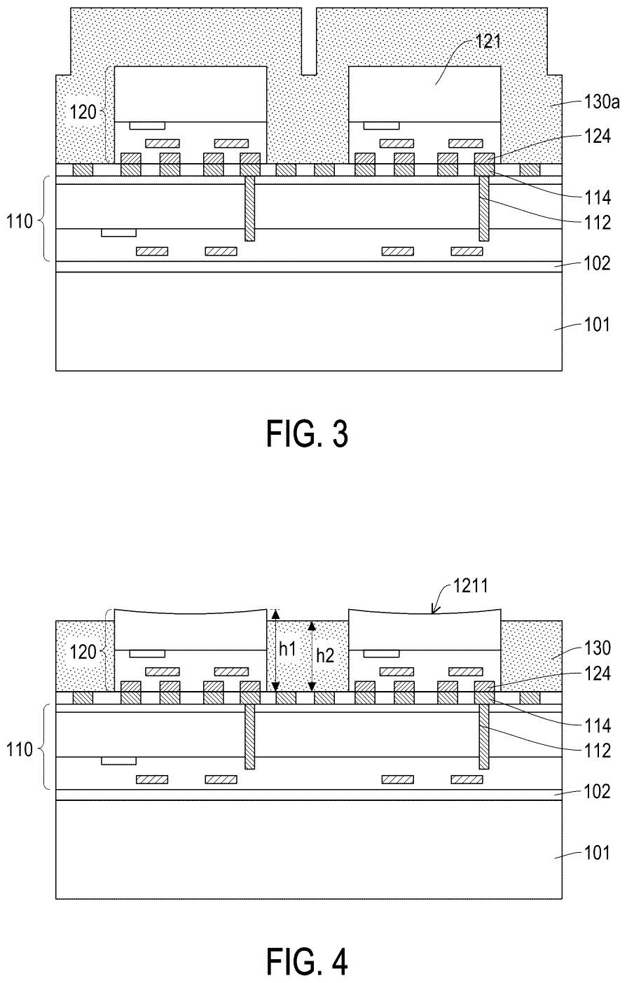

Referring to FIG. 3, an encapsulating material 130a is provided over the wafer 110 for encapsulating the device die 120. In some embodiments, the encapsulating material 130a may be an oxide, such as silicon oxide, and is formed by a suitable formation method such as PCV, CVD, or the like. Although oxide is used as an example of the encapsulating material 130a, the encapsulating material 130a may be formed of other suitable materials, such as polymer, molding compound, molding underfill, epoxy, and/or resin. Accordingly, the encapsulating material 130a may be conformally covering upper surfaces of the wafer 110 and the device dies 120 with a uniform thickness as shown in FIG. 3. In the embodiment, an upper surface of the encapsulating material 130a is a non-planar surface, which conforms to the profile of the wafer 110 and the device dies 120. In one embodiment, the encapsulating material 130a may include base material, which may be a polymer, a resin, an epoxy, or the like, and filler particles in the base material. The base material may be a carbon-based polymer. The filler particles may be the particles of a dielectric material(s) such as SiO₂, Al₂O₃, silica, the compound of iron (Fe), the compound of sodium (Na), or the like, and may have spherical shapes. Also, the spherical filler particles may have the same or different diameters. The disclosure is not limited thereto.

Then, referring to FIG. 3 and FIG. 4, a (first) thinning process is performed over the encapsulating material 130a, so that the encapsulating material 130 being thinned and flattened reveals the back surface of the device dies 120. In some embodiments, the thinning process includes chemical mechanical polishing (CMP) process. After the thinning process is performed, a height h2 of the encapsulating material 130 is substantially lower than a maximum height h1 of each of the device dies 120. Accordingly, the back surface of the encapsulating material 130 is lower than the back surface of the device die 120, so as to cause a step difference at an interface between the encapsulating material 130 and the device die 120, and a valley portion (i.e., concave) corresponds to the encapsulating material 130.

In addition, a dishing effect occurs in the thinning process, which causes the center portion of the substrate 121 of the devices die 120 is formed into a concave dish-shape by the difference in polishing rates on the back surface 1211 of the substrates 121 of the device dies 120. Accordingly, the back surface 1211 of the device die 120 includes a dish-shape concave as shown in FIG. 4. As such, difficulties arise in the later bonding process, so a filling material (e.g., the filling material 150a shown in FIG. 6) is usually provided for compensating the step difference causing by thinning process. Oxide is generally used as the filling material since it is formed by chemical vapor deposition (CVD) for depositing in greater thickness. However, the filling material formed of oxide possesses low thermal conductivity of approximately 1.3 W/m.K, which would significantly reduce the heat dissipation efficiency of the semiconductor package.

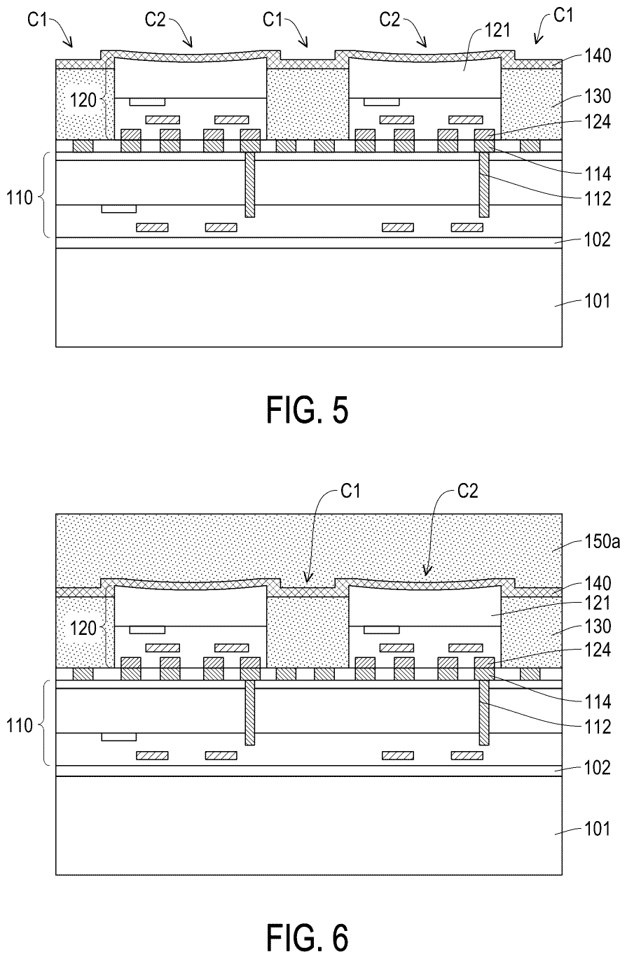

Accordingly, referring to FIG. 5, in some embodiments, after the thinning process, a thermal conductive layer 140 is conformally deposited over the device dies 120 and the encapsulating material 130. In some embodiments, the material of the thermal conductive layer 140 includes aluminum nitride, silicon carbide, silicon nitride, or the like, and can be formed by physical vapor deposition (PVD) process, or chemical vapor deposition (CVD) process, etc. The thermal conductivity of the thermal conductive layer 140 is at least greater than about 50 W/m.K. In the present embodiment, the thermal conductive layer 140 includes aluminum nitride (AlN) and is formed by PVD process, so as to conformally covering the device dies 120 and the encapsulating material 130 with uniform thickness. Aluminium nitride (AlN) is a solid nitride of aluminium, which is an electrical insulator with high thermal conductivity of up to 321 W/(m.K). Silicon carbide (SiC) can be formed by CVD process with greater thickness, and has high thermal conductivity of 120 W/(m.K), and a pure SiC mono-crystals exhibit a room temperature thermal conductivity (K_{T}) of 490 W/(m.K). In some embodiments, a thickness of the thermal conductive layer 140 is substantially equal to or smaller than about 3 kA.112

Accordingly, there is at least one step difference at an upper surface of the thermal conductive layer 140. For example, one of the step difference (i.e., valley portions C1) is at a location corresponding to an interface between the encapsulating material 120 and the device dies 120, and one of the step difference (i.e., concaves C2) is at a location corresponding to the back surfaces of the device dies 120. In other words, the profile of the thermal conductive layer 140 includes valley portions C1, wherein the location of the valley portion C1 corresponds to the encapsulating material 130 with lower height. In addition, the thermal conductive layer 140 conformally covering an inner surface of the concaves at the back surfaces of the device dies 120. In the present embodiments, the thermal conductive layer 140 completely fills the concaves.

Then, referring to FIG. 6, a filling material 150a is provided over the thermal conductive layer 140 for filling the step difference (i.e., the valley portions C1 and the concaves C2) of the thermal conductive layer 140. The thermal conductivity of the thermal conductive layer 140 is higher than the thermal conductivity of the filling material 150, so as to improve the heat dissipation efficiency of the semiconductor package. In the present embodiments, the material of the filling material 150a may be the same as that of the encapsulating material 130, which includes oxide, such as silicon oxide, and is formed by CVD, or the like. In other embodiments, the filling material 150a may also be formed of other suitable materials, such as polymer, molding compound, molding underfill, epoxy, and/or resin. In one embodiment, the filling material 150a may include base material, which may be a polymer, a resin, an epoxy, or the like, and filler particles in the base material. The base material may be a carbon-based polymer. The filler particles may be the particles of a dielectric material(s) such as SiO₂, Al₂O₃, silica, the compound of iron (Fe), the compound of sodium (Na), or the like, and may have spherical shapes. Also, the spherical filler particles may have the same or different diameters. The disclosure is not limited thereto. At this stage, the filling material 150a completely covers a non-planar upper surface of the thermal conductive layer 140.

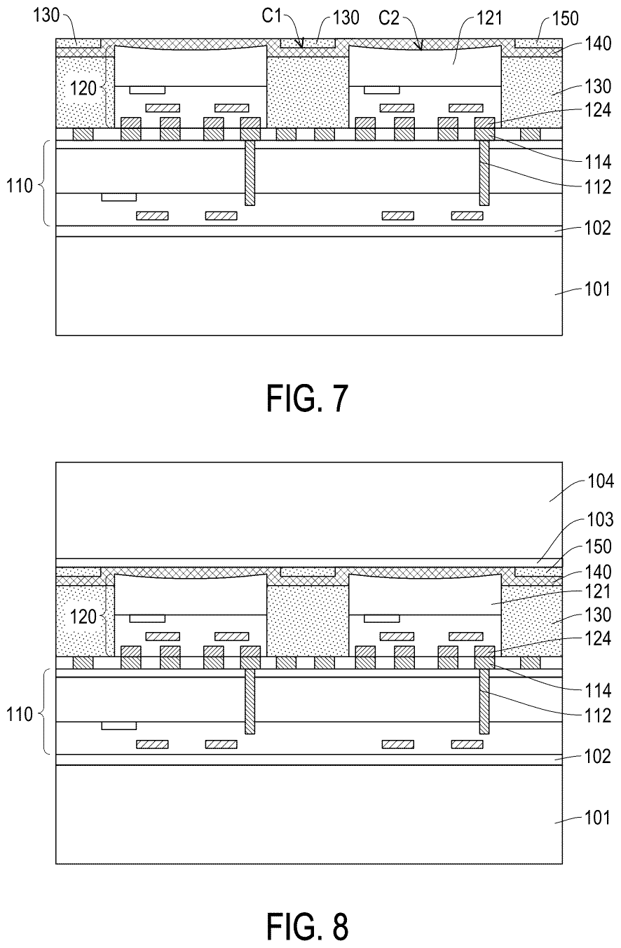

Then, referring to FIG. 6 and FIG. 7, another (second) thinning process is performed over the filling material 150a until the thermal conductive layer 140 is revealed. Accordingly, after the second thinning process, the upper surface of the thermal conductive layer 140 is substantially coplanar with an upper surface of the filling material 150, so as to provide a planar bonding surface for the later bonding process. In the embodiment, the filling material 150 compensates the step difference on the non-planar upper surface of the thermal conductive layer 140 and fills the valley portions C1, while the concaves C2 on the back surface of the device dies 120 are filled by the thermal conductive layer 140.

Then, referring to FIG. 8, a carrier 104 is bonded to the thermal conductive layer 140 and the filling material 150 through a bonding layer 103. In some embodiments, the resulting structure shown in FIG. 7 is not thick enough, so the carrier 104 (i.e., a supporting substrate) is bonded to the resulting structure to provide mechanical strength. In some embodiments, the carrier 104 may be a blank substrate formed of a homogenous material such as silicon, and no devices are formed on/in the carrier 104. In accordance with some embodiments, the bonding layer 103 may be an adhesive film such as a thermal interface material (TIM), or the like. In other embodiments, the carrier 104 may be bonded to the thermal conductive layer 140 and the filling material 150 through fusion bonding. In an example of the attachment, an oxide layer, such as a silicon oxide layer, may be formed on the surface of the carrier 104, for example, through thermal oxidation, for performing fusion bonding.

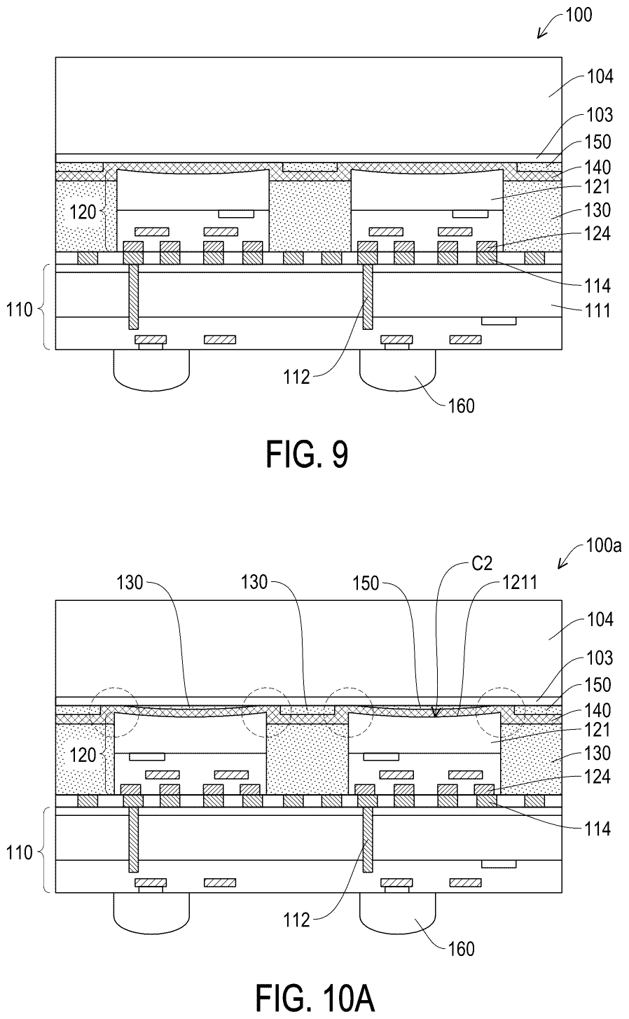

Then, referring to FIG. 9, the resulting structure shown in FIG. 8 is separated from the carrier 101. That is, the carrier 101 are removed along with the de-bonding layer 102. In some embodiments, the de-bonding layer 102 is irradiated by an UV laser such that the overlying structure is peeled from the carrier 101. Then, the structure may be turned upside down, and a plurality of conductive terminals 160 are mounted over the exposed wafer 110, so as to electrically connect the wafer 110. In some embodiments, a plurality of dies, such as IPD dies, IVR dies, memory dies or the like, may also be mounted on the wafer 110. In some embodiments, a plurality of under-ball metallurgy (UBM) patterns are formed under the conductive terminals 160 for ball mount. In some embodiments, after the conductive terminals 160 are formed, a singulation process is performed to form a plurality of semiconductor packages 100. Accordingly, the wafer 110 is diced into a plurality of (first) dies 110 where the device dies 120 are bonded over. At this point, a semiconductor package 100 shown in FIG. 9 is fabricated.

With such configuration, the thermal conductive layer 140, which has higher thermal conductivity than the filling material, conformally covering the step difference between the encapsulating material 130 and the device dies 120, and then providing the filling material 150 to compensate the step difference at the upper surface of the thermal conductive layer 140. As such, the device dies 120 can be thermally coupled to the carrier 104 through the thermal conductive layer 140 instead of the filling material 150 with low thermal conductivity. Therefore, the heat generated by the device dies 120 and/or the die 110 can be sequentially conducted to the thermal conductive layer 140, the bonding layer 104, and then to the carrier 104, so as to be dissipated to exterior environment and improve the heat dissipation of the semiconductor package.

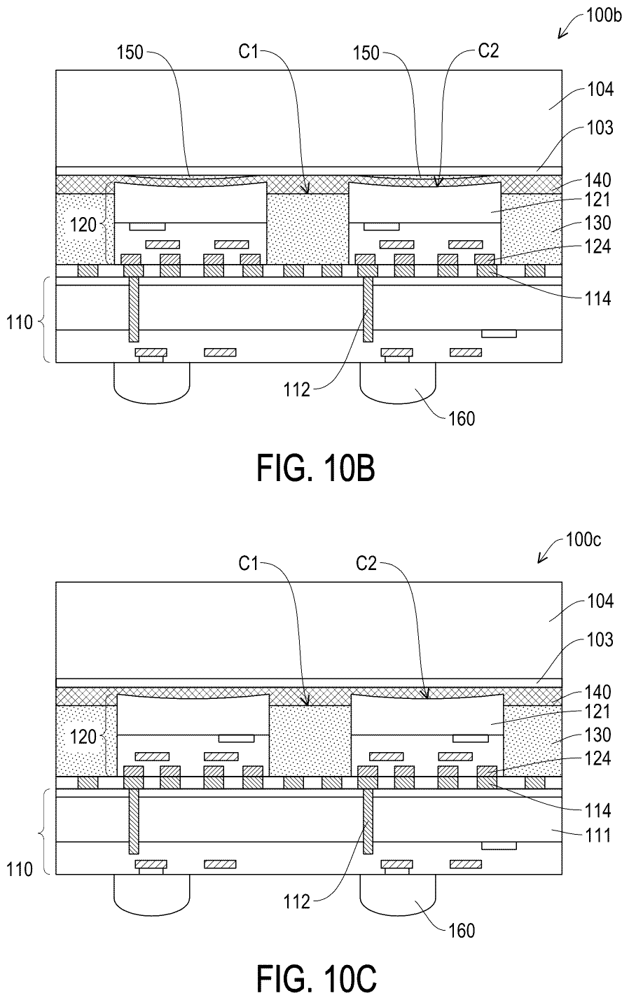

FIG. 10A illustrates a partial cross sectional view of the semiconductor package according to some embodiments of the present disclosure. The semiconductor package 100a illustrated in FIG. 10A is similar to the semiconductor package 100 illustrated in FIG. 9, hence the same reference numerals are used to refer to the same and liked parts, and its detailed description will be omitted herein. The difference between the semiconductor package 100 and the semiconductor package 100a is the concave C2 being filled by both the thermal conductive layer 140 and the filling material 150. Referring to FIG. 10A, in some embodiments, the back surface 1211 of the device die 120 includes a concave C2 caused by the CMP process. In the present embodiment, the depth of the concave C2 may be slightly greater than the thickness of the thermal conductive layer 140, so that when the thermal conductive layer 140 conformally covers an inner surface of the concave C2, the thermal conductive layer 140 may not be able to completely fill the concave C2, and the filling material 150 deposited later on fills the rest part of the concave C2. That is, the thermal conductive layer 140 and the filling material 150 together fill the concave C2 at the back surface 1211 of the device die 120.

In this embodiment, the filling material 150 merely covers the concave C2 at the central portion of the back surface 1211 and the peripheral portion of the back surface 1211 is still covered by the thermal conductive layer 140 and directly bonded to the carrier 104 without the filling material 150 interposed in between. Therefore, the device dies 120 can still be thermally coupled to the carrier 104 through the thermal conductive layer 140, and the heat generated by the device dies 120 can be conducted through the thermal conductive layer 140 to the carrier 104 and be dissipated to the exterior environment. It is noted that “central” and “peripheral” herein may not be interpreted literally but rather be deemed as spatially relative terms, which are intended to encompass different orientations of the device in use or operation in addition to the orientation depicted in the figures.

FIG. 10B illustrates a partial cross sectional view of the semiconductor package according to some embodiments of the present disclosure. The semiconductor package 100b illustrated in FIG. 10B is similar to the semiconductor packages shown in the previous embodiments, hence the same reference numerals are used to refer to the same and liked parts, and its detailed description will be omitted herein. The difference between the semiconductor package 100 and the semiconductor package 100a is that the concaves C2 at the back of the device dies 120 are filled by both the thermal conductive layer 140 and the filling material 150 while the valley portions C1 corresponding to the encapsulating material 130 are completely filled by the thermal conductive layer 140. Referring to FIG. 10B, in some embodiments, the back surface 1211 of the device die 120 includes a concave C2 caused by the CMP process. In the present embodiment, the depth of the concave C2 may be slightly greater than the thickness of the thermal conductive layer 140, so that when the thermal conductive layer 140 conformally covers an inner surface of the concave C2, the thermal conductive layer 140 may not be able to completely fill the concave C2, and the filling material 150 deposited later on fills the rest part of the concave C2. That is, the thermal conductive layer 140 and the filling material 150 together fill the concave C2 at the back surface 1211 of the device die 120.

In the present embodiment, the depth of the valley portions C1 may be substantially equal to or smaller than the thickness of the thermal conductive layer 140, so that when the thermal conductive layer 140 conformally covers an inner surface of the concave C2, the thermal conductive layer 140 may not be able to completely fill the concave C2, but be able to completely fill the valley portions C1, so that the filling material 150 deposited later on fills the rest part of the concave C2. That is, the thermal conductive layer 140 and the filling material 150 together fill the concave C2 at the back surface 1211 of the device die 120 while the thermal conductive layer 140 completely fills the valley portions C1 without the filling material 150.

FIG. 10C illustrates a partial cross sectional view of the semiconductor package according to some embodiments of the present disclosure. The semiconductor package 100c illustrated in FIG. 10C is similar to the semiconductor packages shown in the previous embodiments, hence the same reference numerals are used to refer to the same and liked parts, and its detailed description will be omitted herein. The difference between the semiconductor package 100c and the previous semiconductor packages is that the thermal conductive layer 140 completely fills the valley portions C1 and the concaves C2 without any filling material. In the embodiments, the material of the thermal conductive layer 140 may include silicon carbide, silicon nitride, or the like, which can be formed by CVD process with greater thickness, so as to completely fill the valley portions C1 corresponding to the encapsulating material 130 and the concaves C2 at the back surface of the device dies 120.

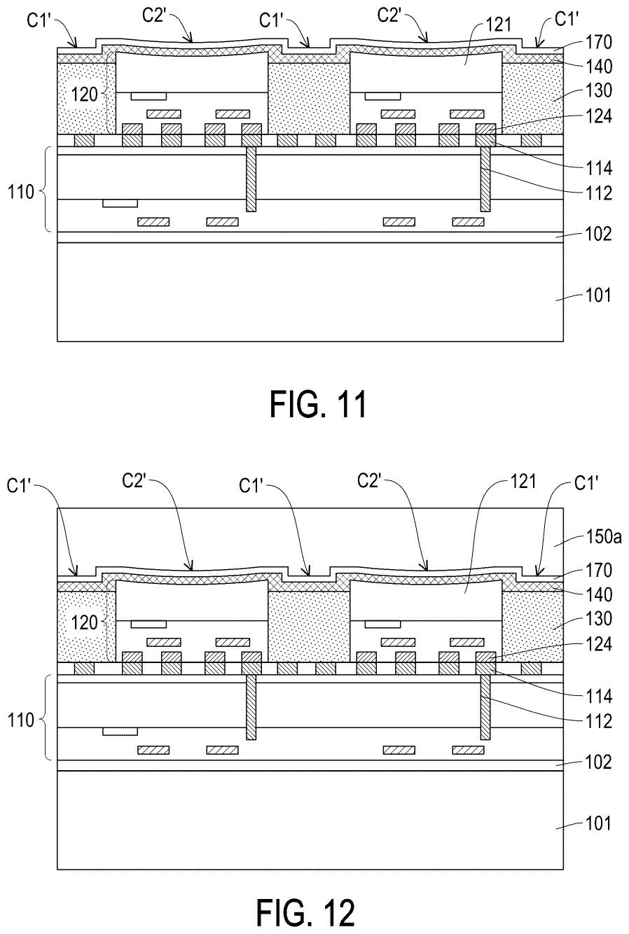

FIG. 11 to FIG. 15 illustrates a cross sectional views of intermediate stages in the manufacturing of a semiconductor package according to some embodiments of the present disclosure. It is noted that the semiconductor package 100d and the manufacturing process thereof shown in FIG. 11 to FIG. 15 contains many features same as or similar to the previous embodiments disclosed earlier with FIG. 1 to FIG. 10. For purpose of clarity and simplicity, detail description of same or similar features may be omitted, and the same or similar reference numbers denote the same or like components.

Referring to FIG. 11, in the present embodiment, the step shown in FIG. 11 is performed after the step the thermal conductive layer 140 is formed, i.e., the step shown in FIG. 5. After the thermal conductive layer is conformally deposited over the device dies 120 and the encapsulating material 130, a polishing stop layer 170 is conformally deposited over the thermal conductive layer 140, so that the polishing stop layer 170 conformally covers the non-planar upper surface of the thermal conductive layer 140. In some embodiments, the material of the polishing stop layer 170 includes silicon carbide, silicon nitride, or the like, and can be formed by physical vapor deposition (PVD) process, or chemical vapor deposition (CVD) process, etc. The thermal conductivity of the polishing stop layer 170 is also greater than the thermal conductivity of the filling material 150. In some embodiments, the thermal conductivity of the polishing stop layer 170 may be smaller than or substantially equal to that of the thermal conductive layer 140 and is greater than the thermal conductivity of the filling material 150.

In some embodiments, the production cost of the thermal conductive layer 140 (e.g., AlN layer) is pretty high and the thickness of the thermal conductive layer 140 is usually thinner than 3 ka, so it is easy to polishing off the thermal conductive layer 140 during the later on thinning (CMP) process. The polishing stop layer 170 provides an adequate hard stop over the thermal conductive layer 140. Therefore, by adding the polishing stop layer 170 between the thermal conductive layer 140 and the filling material 150 can protect the thermal conductive layer 140 from being damage or even removed during the CMP process.

Since the polishing stop layer 170 is conformally deposited over the thermal conductive layer 140, there is at least one step difference at an upper surface of the polishing stop layer 170. For example, one of the step difference (i.e., valley portions C1′) is at a location corresponding to an interface between the encapsulating material 120 and the device dies 120, and one of the step difference (i.e., concaves C2′) is at a location corresponding to the back surfaces of the device dies 120. In the present embodiments, the thermal conductive layer 140 and the polishing stop layer 170 completely fills the concaves at the back surfaces of the device dies.

Then, referring to FIG. 12, a filling material 150a is provided over the polishing stop layer 170 for filling the step difference (i.e., the valley portions C1′ and the concaves C2′) of the polishing stop layer 170. In the present embodiments, the material of the filling material 150a may be the same as that of the encapsulating material 130, which includes oxide, such as silicon oxide, and is formed by CVD, or the like. In other embodiments, the filling material 150a may also be formed of other suitable materials, such as polymer, molding compound, molding underfill, epoxy, and/or resin. In one embodiment, the filling material 150a may include base material, which may be a polymer, a resin, an epoxy, or the like, and filler particles in the base material. The base material may be a carbon-based polymer. The filler particles may be the particles of a dielectric material(s) such as SiO₂, Al₂O₃, silica, the compound of iron (Fe), the compound of sodium (Na), or the like, and may have spherical shapes. Also, the spherical filler particles may have the same or different diameters. The disclosure is not limited thereto. At this stage, the filling material 150a completely covers a non-planar upper surface of the polishing stop layer 170.

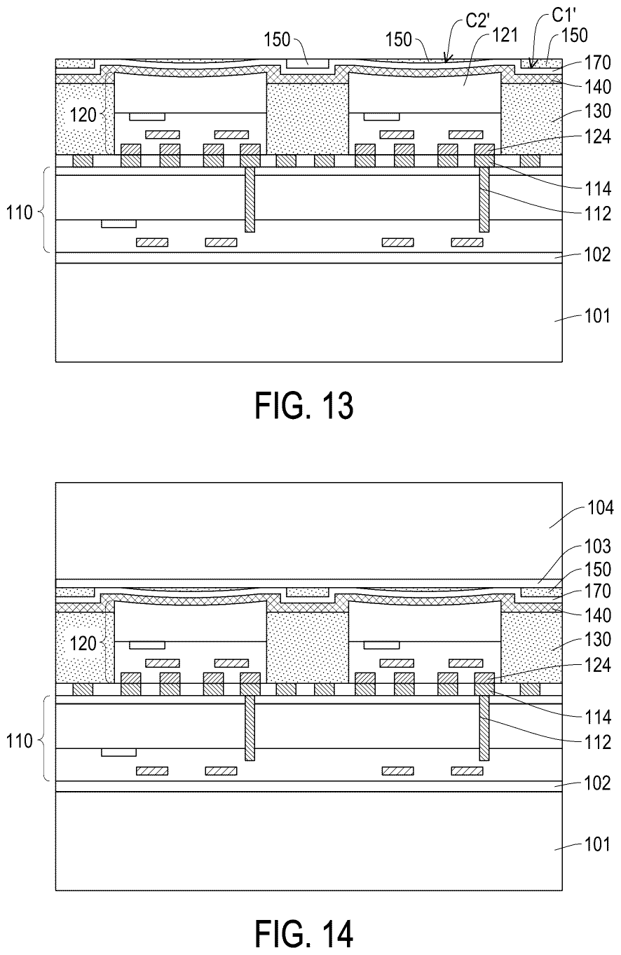

Then, referring to FIG. 12 and FIG. 13, a thinning process is performed over the filling material 150a until it reaches and stops at the polishing stop layer 170. Accordingly, after the thinning process, the upper surface of the polishing stop layer 170 is substantially coplanar with an upper surface of the filling material 150, so as to provide a planar bonding surface for the later bonding process. In the embodiment, the filling material 150 compensates the step difference on the non-planar upper surface of the polishing stop layer 170 and fills the valley portions C1′ and the concaves C2′.

Then, referring to FIG. 14, the carrier 104 is bonded to the polishing stop layer 170 and the filling material 150 through a bonding layer 103 to provide mechanical strength to the device dies 120 and the encapsulating material 130. In some embodiments, the carrier 104 may be a blank substrate formed of a homogenous material such as silicon, and no devices are formed on/in the carrier 104. In accordance with some embodiments, the bonding layer 103 may be an adhesive film such as a thermal interface material (TIM), or the like. In other embodiments, the carrier 104 may be bonded to the polishing stop layer 170 and the filling material 150 through fusion bonding. In an example of the attachment, an oxide layer, such as a silicon oxide layer, may be formed on the surface of the carrier 104, for example, through thermal oxidation, for performing fusion bonding.

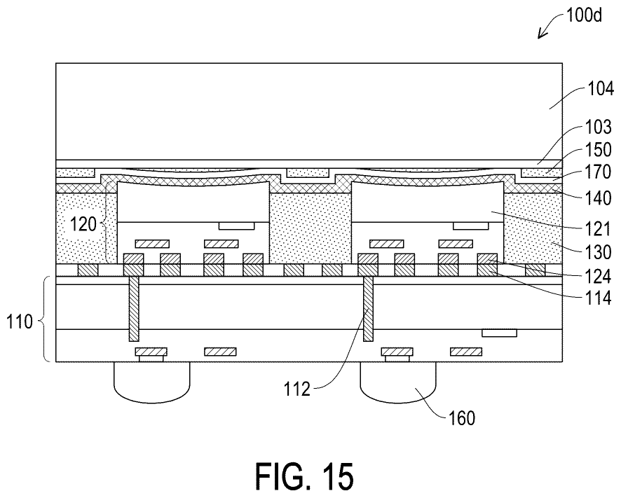

Then, referring to FIG. 15, the resulting structure shown in FIG. 14 is separated from the carrier 101. That is, the carrier 101 are removed along with the de-bonding layer 102. In some embodiments, the de-bonding layer 102 is irradiated by an UV laser such that the overlying structure is peeled from the carrier 101. Then, the structure may be turned upside down, and a plurality of conductive terminals 160 are mounted over the exposed wafer 110, so as to electrically connect the wafer 110. In some embodiments, a plurality of dies, such as IPD dies, IVR dies, memory dies or the like, may also be mounted on the wafer 110. In some embodiments, a plurality of under-ball metallurgy (UBM) patterns are formed under the conductive terminals 160 for ball mount. In some embodiments, after the conductive terminals 160 are formed, a singulation process is performed to form a plurality of semiconductor packages 100d. Accordingly, the wafer 110 is diced into a plurality of (first) dies 110 where the device dies 120 are bonded over. At this point, a semiconductor package 100d shown in FIG. 15 is fabricated.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a substrate, a device die, an encapsulating material, a thermal conductive layer, a filling material, and a carrier. The device die is disposed over the substrate. The encapsulating material is disposed over the substrate and laterally encapsulates the device die. The thermal conductive layer conformally covers the device die and the encapsulating material, wherein a profile of the thermal conductive layer comprises a valley portion. The filling material is disposed over the thermal conductive layer and fills the valley portion, wherein a thermal conductivity of the thermal conductive layer is higher than a thermal conductivity of the filling material. The carrier is bonded to the thermal conductive layer and the filling material. In one embodiment, a back surface of the encapsulating material is lower than a back surface of the device die, and the location of the valley portion corresponds to the encapsulating material. In one embodiment, a back surface of the device die comprises a concave, and the thermal conductive layer fills the concave. In one embodiment, a back surface of the device die comprises a concave, and the thermal conductive layer conformally covering an inner surface of the concave and the filling material fills the concave. In one embodiment, an upper surface of the thermal conductive layer is substantially coplanar with an upper surface of the filling material. In one embodiment, the thermal conductive layer comprises aluminum nitride, silicon carbide, or silicon nitride. In one embodiment, the semiconductor package further includes a polishing stop layer conformally covering an upper surface of the thermal conductive layer and disposed between the thermal conductive layer and the filling material. In one embodiment, the substrate comprises a plurality of through vias extending through the substrate. In one embodiment, the carrier is bonded to the thermal conductive layer and the filling material through a bonding layer.

In accordance with some embodiments of the disclosure, a semiconductor package includes a first die, a second die, an encapsulating material, a thermal conductive layer, a filling material, and a carrier. The second die is disposed over the first die. The encapsulating material is over the first die and laterally encapsulating the second die. The thermal conductive layer conformally covers the second die and the encapsulating material, wherein there is a step difference at an upper surface of the thermal conductive layer. The filling material is disposed over the thermal conductive layer for compensating the step difference, wherein a thermal conductivity of the thermal conductive layer is higher than a thermal conductivity of the filling material. The carrier is bonded to the thermal conductive layer and the filling material. In one embodiment, the step difference is at a location corresponding to an interface between the encapsulating material and the device die. In one embodiment, the step difference is at a location corresponding to a back surface of the device die. In one embodiment, the upper surface of the thermal conductive layer is substantially coplanar with an upper surface of the filling material. In one embodiment, the semiconductor package further includes a polishing stop layer conformally covering the upper surface of the thermal conductive layer and disposed between the thermal conductive layer and the filling material. In one embodiment, an upper surface of the polishing stop layer is substantially coplanar with an upper surface of the filling material. In one embodiment, the polishing stop layer comprises silicon carbide, or silicon nitride.

In accordance with some embodiments of the disclosure, a manufacturing method of a semiconductor package includes the following steps. A wafer is provided. A device die is bonded over the wafer. An encapsulating material is provided over the wafer for encapsulating the device die. A first thinning process is performed over the encapsulating material for revealing a back surface of the device die. A thermal conductive layer conformally deposits over the device die and the encapsulates material, wherein a profile of the thermal conductive layer includes a valley portion. A filling material is provided over the thermal conductive layer for filling the valley portion, wherein a thermal conductivity of the thermal conductive layer is higher than a thermal conductivity of the filling material. A second thinning process is performed over the filling material. A carrier is bonded to the thermal conductive layer and the filling material. In one embodiment, the thermal conductive layer is formed by physical vapor deposition. In one embodiment, the semiconductor package further includes: conformally depositing a polishing stop layer over the thermal conductive layer. In one embodiment, the carrier is bonded to the thermal conductive layer and the filling material through a bonding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a device die disposed over the substrate;
an encapsulating material over the substrate and laterally encapsulating the device die;
a thermal conductive layer conformally covering the device die and the encapsulating material, wherein a profile of the thermal conductive layer comprises a valley portion;
a filling material disposed over the thermal conductive layer and filling the valley portion, wherein a thermal conductivity of the thermal conductive layer is higher than a thermal conductivity of the filling material; and
a carrier bonded to the thermal conductive layer and the filling material.

2. The semiconductor package as claimed in claim 1, wherein a back surface of the encapsulating material is lower than a back surface of the device die, and the location of the valley portion corresponds to the encapsulating material.

3. The semiconductor package as claimed in claim 1, wherein a back surface of the device die comprises a concave, and the thermal conductive layer fills the concave.

4. The semiconductor package as claimed in claim 1, wherein a back surface of the device die comprises a concave, and the thermal conductive layer conformally covering an inner surface of the concave and the filling material fills the concave.

5. The semiconductor package as claimed in claim 1, wherein an upper surface of the thermal conductive layer is substantially coplanar with an upper surface of the filling material.

6. The semiconductor package as claimed in claim 1, wherein the thermal conductive layer comprises aluminum nitride, silicon carbide, or silicon nitride.

7. The semiconductor package as claimed in claim 1, further comprising a polishing stop layer conformally covering an upper surface of the thermal conductive layer and disposed between the thermal conductive layer and the filling material.

8. The semiconductor package as claimed in claim 1, wherein the substrate comprises a plurality of through vias extending through the substrate.

9. The semiconductor package as claimed in claim 1, wherein the carrier is bonded to the thermal conductive layer and the filling material through a bonding layer.

10. A semiconductor package, comprising:
a first die;
a second die disposed over the first die;
an encapsulating material over the first die and laterally encapsulating the second die;
a thermal conductive layer conformally covering the second die and the encapsulating material, wherein there is a step difference at an upper surface of the thermal conductive layer;
a filling material disposed over the thermal conductive layer for compensating the step difference, wherein a thermal conductivity of the thermal conductive layer is higher than a thermal conductivity of the filling material; and
a carrier bonded to the thermal conductive layer and the filling material.

11. The semiconductor package as claimed in claim 10, wherein the step difference is at a location corresponding to an interface between the encapsulating material and the device die.

12. The semiconductor package as claimed in claim 10, wherein the step difference is at a location corresponding to a back surface of the device die.

13. The semiconductor package as claimed in claim 10, wherein the upper surface of the thermal conductive layer is substantially coplanar with an upper surface of the filling material.

14. The semiconductor package as claimed in claim 10, further comprising a polishing stop layer conformally covering the upper surface of the thermal conductive layer and disposed between the thermal conductive layer and the filling material.

15. The semiconductor package as claimed in claim 14, wherein an upper surface of the polishing stop layer is substantially coplanar with an upper surface of the filling material.

16. The semiconductor package as claimed in claim 1, wherein the polishing stop layer comprises silicon carbide, or silicon nitride.

17. A manufacturing method of a semiconductor package, comprising:
providing a wafer;
bonding a device die over the wafer;
providing an encapsulating material over the wafer for encapsulating the device die;
performing a first thinning process over the encapsulating material for revealing a back surface of the device die;
conformally depositing a thermal conductive layer over the device die and the encapsulating material, wherein a profile of the thermal conductive layer comprises a valley portion;
providing a filling material over the thermal conductive layer for filling the valley portion, wherein a thermal conductivity of the thermal conductive layer is higher than a thermal conductivity of the filling material;
performing a second thinning process over the filling material; and
bonding a carrier to the thermal conductive layer and the filling material.

18. The manufacturing method of the semiconductor package as claimed in claim 17, wherein the thermal conductive layer is formed by physical vapor deposition.

19. The semiconductor package as claimed in claim 1, further comprising:
conformally depositing a polishing stop layer over the thermal conductive layer.

20. The semiconductor package as claimed in claim 1, wherein the carrier is bonded to the thermal conductive layer and the filling material through a bonding layer.
